(19) United States
(12) Patent Application Publication
(10) Pub. No.: US 2024/0284801 A1
(43) Pub. Date: Aug. 22, 2024

(54) EXCITATION CIRCUIT, VIBRATION DEVICE, AND VEHICLE

(71) Applicant: Murata Manufacturing Co., Ltd., Nagaokakyo-shi (JP)

(72) Inventors: Noritaka KISHI, Nagaokakyo-shi (JP); Masaaki TAKATA, Nagaokakyo-shi (JP); Satoshi ICHIHARA, Nagaokakyo-shi (JP)

(21) Appl. No.: 18/637,607

(22) Filed: Apr. 17, 2024

Related U.S. Application Data
(63) Continuation of application No. PCT/JP2022/024577, filed on Jun. 20, 2022.

(30) Foreign Application Priority Data
Nov. 10, 2021 (JP) 2021-183592

(51) Int. Cl. H10N 30/80; H10N 30/20; H10N 30/88

(52) U.S. Cl. CPC H10N 30/802; H10N 30/2027; H10N 30/883

(57) ABSTRACT

An excitation circuit includes an output circuit including a series circuit including first and second switches connected to a DC power supply, and including a connection point between the first and second switches to which a piezoelectric element is connected, a current detection circuit to detect at least one of currents flowing through the first and second switches, and output a detection signal indicating a value based on the detected current, and a control circuit to execute switching processing in which the first and second switches are complementarily switched on and off at a predetermined frequency, in order to apply a voltage of the predetermined frequency from the output circuit to the piezoelectric element, and including a search mode to determine a resonant frequency of a vibrator vibrated by the piezoelectric element based on a value indicated by the detection signal outputted from the current detection circuit.

### CROSS REFERENCE TO RELATED APPLICATIONS

This application claims the benefit of priority to Japanese Patent Application No. 2021-183592 filed on Nov. 10, 2021 and is a Continuation Application of PCT Application No. PCT/JP2022/024577 filed on Jun. 20, 2022. The entire contents of each application are hereby incorporated herein by reference.

### BACKGROUND OF THE INVENTION

### 1. Field of the Invention

The present disclosure relates to excitation circuits, vibration devices, and vehicles.

### 2. Description of the Related Art

There have been studies on technologies to clean a lens by vibrating the lens using vibration of a piezoelectric element caused by applying a drive signal having a frequency component to the piezoelectric element. For example, U.S. Pat. No. 10,401,618 discloses an ultrasonic cleaning system for cleaning a lens, in which a vibration drive signal is applied to an ultrasonic vibrator and a driver integrated circuit controls the frequency of the drive signal based on a current detection signal indicating a drive current flowing through the vibrator.

### SUMMARY OF THE INVENTION

Using the technology disclosed in U.S. Pat. No. 10,401,618, a piezoelectric element provided in a predetermined device can vibrate the device in a predetermined vibration mode when driven at a resonant frequency. However, when a control circuit drives the piezoelectric element with a unipolarity to detect the magnitude of a drive current, which is a signal having a predetermined frequency, electrochemical migration of the piezoelectric element is facilitated, which may lead to failure.

Example embodiments of the present invention provide excitation circuits, vibration devices, and vehicles that each can detect a magnitude of a current flowing through a piezoelectric element while reducing the possibility of electrochemical migration occurring in the piezoelectric element.

An excitation circuit according to an example embodiment of the present disclosure includes an output circuit including a series circuit of a first switch and a second switch connected to a DC power supply, and including a connection point, between the first switch and the second switch, to which a piezoelectric element is connected, a current detection circuit to detect at least one of a current flowing through the first switch and a current flowing through the second switch and output a detection signal indicating a value based on the detected current, and a control circuit to execute switching processing in which the first switch and the second switch are complementarily switched on and off at a switching frequency corresponding to a predetermined frequency, in order to apply a voltage of the predetermined frequency from the output circuit to the piezoelectric element, and that includes a search mode to determine a resonant frequency of a vibrator including an object vibrated by the piezoelectric element and the piezoelectric element, based on a value indicated by the detection signal outputted from the current detection circuit.

A vibration device according to an example embodiment of the present disclosure includes the excitation circuit, the piezoelectric element, and a light transmissive protective cover vibrated by the piezoelectric element.

A vehicle according to an example embodiment of the present disclosure includes the vibration device, and an imaging device to detect light transmitted through the protective cover.

Example embodiments of the present disclosure provide excitation circuits, vibration devices, and vehicles that each can detect the magnitude of a current flowing through a piezoelectric element while reducing the possibility of electrochemical migration occurring in the piezoelectric element.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a vibration device according to a first example embodiment of the present invention.

FIG. 2 is a schematic cross-sectional view of a configuration of an imaging unit according to the first example embodiment of the present invention.

FIG. 3 is a schematic circuit diagram of a vibration circuit according to the first example embodiment of the present invention.

FIG. 4 is a graph showing the relationship between a frequency of a drive signal applied to a piezoelectric element and impedance.

FIG. 5 is a timing chart showing input and output signals of each element of an excitation circuit.

FIG. 6A is a graph showing a temporal change in a drive signal having a predetermined resonant frequency applied to the piezoelectric element and a temporal change in a displacement amount of a protective cover when the piezoelectric element is driven at the frequency.

FIG. 6B is a graph showing a temporal change in a drive signal having a predetermined resonant frequency applied to the piezoelectric element and a temporal change in the displacement amount of the protective cover when the piezoelectric element is driven at a frequency that is about ⅓ times the frequency.

FIG. 7A is a graph showing an example of control using a first sweep method for a control circuit to determine the resonant frequency.

FIG. 7B is a graph showing an example of control using a second sweep method for the control circuit to determine the resonant frequency.

FIG. 7C is a graph showing an example of control using a third sweep method for the control circuit to determine the resonant frequency.

FIG. 8 is a graph showing the impedance of the piezoelectric element with respect to a switching frequency near the resonant frequency and a phase difference between the voltage applied to the piezoelectric element and a current flowing through the piezoelectric element.

FIG. 9 is a schematic circuit diagram showing a modification of the excitation circuit according to the first example embodiment of the present invention.

FIG. 10 is a flowchart for explaining vibration processing of the vibration device by the control circuit of the excitation circuit according to the first example embodiment of the present invention.

FIG. 11 is a schematic circuit diagram showing an example of a low pass filter of the excitation circuit according to the first example embodiment of the present invention.

FIG. 12 is a schematic circuit diagram showing a modification of the excitation circuit according to the first example embodiment of the present invention.

FIG. 13 is a schematic circuit diagram of a vibration circuit according to a second example embodiment of the present invention.

FIG. 14 is a schematic circuit diagram of a vibration circuit according to a third example embodiment of the present invention.

### DETAILED DESCRIPTION OF THE EXAMPLE EMBODIMENTS

Example embodiments according to the present disclosure will be described below with reference to the drawings. However, the configuration described below is merely an example of the present disclosure, and the present disclosure is not limited to the example embodiments described below. Besides these example embodiments, various changes can be made according to the design and the like without departing from the technical ideas of the present disclosure.

### First Example Embodiment

### 1-1. Configuration Example

An excitation circuit according to a first example embodiment of the present disclosure includes an output circuit including a series circuit of a first switch and a second switch connected to a DC power supply, and including a connection point, between the first switch and the second switch, to which a piezoelectric element is connected, a current detection circuit to detect at least one of a current flowing through the first switch and a current flowing through the second switch, and output a detection signal indicating the detected current, and a control circuit to control a switching frequency of the first switch and the second switch, and including a search mode to determine a resonant frequency of a vibrator including an object vibrated by the piezoelectric element and the piezoelectric element, based on the current indicated by the detection signal outputted from the current detection circuit, by executing switching processing to complementarily switch the first switch and the second switch on and off to apply a voltage having the switching frequency to the piezoelectric element. With this configuration, the control circuit of the excitation circuit can control the frequency of the voltage applied to the piezoelectric element by controlling the switching frequency to execute the switching processing. The control circuit can detect the magnitude of the current flowing through the piezoelectric element even when the average current flowing through the piezoelectric element or the average voltage applied to the piezoelectric element at that frequency is zero. The control circuit can thus determine the resonant frequency of the vibrator. Therefore, the excitation circuit can detect the current flowing through the piezoelectric element while reducing the possibility of electrochemical migration occurring in the piezoelectric element to which a voltage is applied. The excitation circuit can also control the switching frequency to execute the switching processing, based on the magnitude of the detected current.

### 1-1-1. Vibration Device

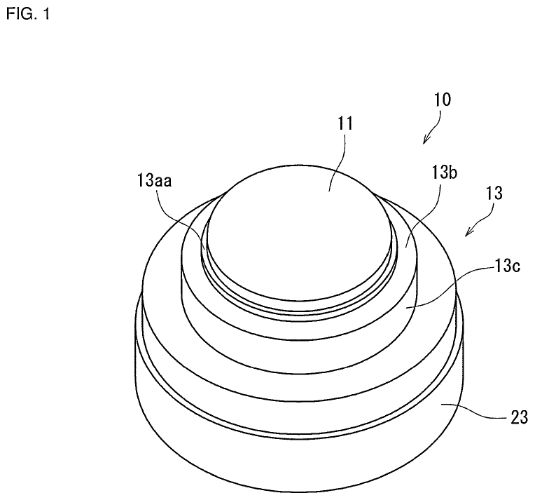

FIG. 1 is a perspective view of a vibration device 10 according to the first example embodiment of the present disclosure. The vibration device 10 according to the first example embodiment includes a protective cover 11, a vibrating body 13, a piezoelectric element 15, and an excitation circuit 31A to be described later. The vibrating body 13 includes a first cylindrical portion 13a, a spring portion 13b, a second cylindrical portion 13c, and a diaphragm 13d. The vibration device 10 and an imaging unit 100 including the vibration device 10 (to be described in detail later) are examples of a device that is vibrated by the excitation circuit 31A according to this example embodiment to be described later, and are not limited thereto. The piezoelectric element 15 vibrates a predetermined object. The object includes the protective cover 11 and the vibrating body 13. The structure including the protective cover 11, the vibrating body 13, and the piezoelectric element 15 has a predetermined resonant frequency to be described later with respect to the vibration of the piezoelectric element 15. This structure is hereinafter referred to as a vibrator 17.

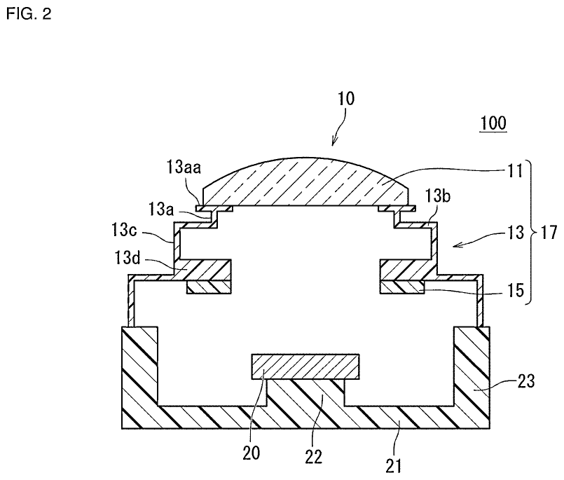

The protective cover 11 transmits light of a predetermined wavelength. The predetermined wavelength is, for example, a wavelength detected by an imaging device 20 (see FIG. 2) of the imaging unit 100. The predetermined wavelength is not limited to a wavelength in the visible light region, but may be a wavelength in the invisible light region.

The protective cover 11 is supported by an end portion of the first cylindrical portion 13a. Specifically, the protective cover 11 has its back surface supported by the first cylindrical portion 13a.

The protective cover 11 has a hemispherical dome shape. The protective cover 11 has a circular shape when viewed from the height direction of the vibration device 10. Note that the shape of the protective cover 11 is not limited to the circular shape. The shape of the protective cover 11 viewed from the height direction of the vibration device 10 may be polygonal, oval, or the like. The protective cover 11 is not limited to the hemispherical dome shape. For example, the protective cover 11 may have a shape formed by connecting cylinders into a hemisphere, or may have a curved shape smaller than a hemisphere. The protective cover 11 may be a flat plate. The protective cover 11 may have a function as an optical element such as a lens.

The first cylindrical portion 13a preferably has a cylindrical shape having one end and the other end. The first cylindrical portion 13a supports the protective cover 11 at one end. For example, the protective cover 11 and the first cylindrical portion 13a are joined. A method for joining the protective cover 11 and the first cylindrical portion 13a is not particularly limited. Examples of the joining method include bonding with an adhesive, welding, fitting, and press-fitting.

In the first example embodiment, the first cylindrical portion 13a has a flange 13aa at one end. The flange 13aa is a plate-shaped structure extending outward from one end of the first cylindrical portion 13a. The flange 13aa preferably has an annular plate shape. The first cylindrical portion 13a has the flange 13aa increase the contact area with the protective cover 11, thus stably supporting the protective cover 11.

The other end of the first cylindrical portion 13a is supported by the elastically deformable spring portion 13b. In other words, the first cylindrical portion 13a is supported by the spring portion 13b on the opposite side to the protective cover 11 side.

The first cylindrical portion 13a is made of a hollow member with a through-hole provided inside. The through-hole is provided in the height direction of the vibration device 10, and has openings provided at one end and the other end of the first cylindrical portion 13a. The first cylindrical portion 13a preferably has a cylindrical shape, for example. The external shape of the first cylindrical portion 13a and the openings of the through-hole preferably have a circular shape when viewed from the height direction of the vibration device 10.

Note that the shape of the first cylindrical portion 13a is not limited to such a cylindrical shape. For example, the first cylindrical portion 13a may have a polygonal cylindrical shape, an elliptical cylindrical shape, or the like.

The material of the first cylindrical portion 13a may be metal, synthetic resin or the like, for example. The material of the first cylindrical portion 13a may also be ceramic, glass, or the like, which can be molded and/or cut. The same applies to the spring portion 13b, the second cylindrical portion 13c, and the diaphragm 13d.

The spring portion 13b supports the first cylindrical portion 13a so as to be displaceable with respect to the second cylindrical portion 13c. The spring portion 13b is a circular plate spring. The spring portion 13b has its inner peripheral portion supporting the other end of the first cylindrical portion 13a. The spring portion 13b has its outer peripheral portion supported by the second cylindrical portion 13c. The outer peripheral shape and inner peripheral shape of the spring portion 13b are circular when viewed from the height direction of the vibration device 10.

Note that the outer peripheral shape and inner peripheral shape of the spring portion 13b are not limited to such a circular shape. The outer peripheral shape and inner peripheral shape of the spring portion 13b may be polygonal or elliptical when viewed from the height direction of the vibration device 10.

The second cylindrical portion 13c has a cylindrical shape with one end and the other end. One end of the second cylindrical portion 13c supports the outer peripheral portion of the spring portion 13b.

The diaphragm 13d is disposed at the other end of the second cylindrical portion 13c.

Note that the second cylindrical portion 13c is not limited to a cylindrical shape. For example, the second cylindrical portion 13c may have a polygonal cylindrical shape, an elliptical cylindrical shape, or the like.

The diaphragm 13d is disposed at the other end of the second cylindrical portion 13c, and vibrates in the height direction of the vibration device 10. Specifically, the diaphragm 13d is disposed at the other end of the second cylindrical portion 13c, that is, on the bottom surface.

The piezoelectric element 15 is provided on the bottom surface (lower surface) of the diaphragm 13d. The diaphragm 13d vibrates as the piezoelectric element 15 vibrates, causing the second cylindrical portion 13c to vibrate in the height direction of the vibration device 10. For example, the piezoelectric element 15 vibrates upon voltage application.

The piezoelectric element 15 has an annular plate shape. The outer peripheral shape and inner peripheral shape of the piezoelectric element 15 are circular when viewed from the height direction of the vibration device 10. Note that the outer peripheral shape and inner peripheral shape of the piezoelectric element 15 are not limited to such a circular shape. The outer peripheral shape and inner peripheral shape of the piezoelectric element 15 viewed from the height direction of the vibration device 10 may be polygonal or elliptical, for example.

The piezoelectric element 15 includes a piezoelectric body and an electrode. Examples of piezoelectric material include suitable piezoelectric ceramics such as barium titanate (BaTiO₃), lead zirconate titanate (PZT: PbTiO₃, PbZrO₃), lead titanate (PbTiO₃), lead metaniobate (PbNb₂O₆), and bismuth titanate (Bi₄Ti₃O₁₂) (K,Na)NbO₃ or suitable piezoelectric single crystals such as LiTaO₃ and LiNbO₃. The electrode may be a Ni electrode, for example. The electrode may be an electrode made of a metal thin film such as Ag or Au, which is formed by a sputtering method. The electrode can be formed by plating or vapor deposition, other than sputtering.

The diaphragm 13d has an annular plate shape. The diaphragm 13d supports the bottom surface of the second cylindrical portion 13c.

The protective cover 11, the first cylindrical portion 13a, the spring portion 13b, and the second cylindrical portion 13c are configured such that the resonant frequency of the protective cover 11 is larger than the resonant frequency of the spring portion 13b. Specifically, the resonant frequency of the protective cover 11 is set larger than the resonant frequency of the spring portion 13b by determining the materials and dimensions of the protective cover 11, the first cylindrical portion 13a, the spring portion 13b, and the second cylindrical portion 13c described above.

The first cylindrical portion 13a, the spring portion 13b, the second cylindrical portion 13c, and the diaphragm 13d are integrally formed. Note that the first cylindrical portion 13a, the spring portion 13b, the second cylindrical portion 13c, and the diaphragm 13d may be formed separately or may be formed as separate members.

As described above, the vibration device 10 includes the excitation circuit 31A that applies a drive signal to the piezoelectric element 15 to cause vibration. The excitation circuit 31A is connected to the piezoelectric element 15 through a power supply conductor, for example. The piezoelectric element 15 vibrates in the height direction of the vibration device 10 based on the drive signal from the excitation circuit 31A. The vibration of the piezoelectric element 15 causes the diaphragm 13d to vibrate in the height direction of the vibration device 10, and the diaphragm 13d vibrates the second cylindrical portion 13c in the height direction of the vibration device 10. The vibration of the second cylindrical portion 13c can transmit the vibration of the piezoelectric element 15 to the first cylindrical portion 13a through the spring portion 13b. In the vibration device 10, the protective cover 11 is vibrated by the vibration of the first cylindrical portion 13a, thus removing foreign matter such as raindrops adhering to the protective cover 11.

The excitation circuit 31A applies a drive signal to the piezoelectric element 15 so that the first cylindrical portion 13a and the second cylindrical portion 13c vibrate in the height direction of the vibration device 10 in opposite phases. The excitation circuit 31A can vibrate the vibration device 10 in a vibration mode other than the mode in which the first cylindrical portion 13a and the second cylindrical portion 13c vibrate in the height direction of the vibration device 10 in opposite phases based on the drive signal applied to the piezoelectric element 15.

FIG. 2 is a schematic cross-sectional view of a configuration of the imaging unit 100 according to this example embodiment. FIG. 2 is a cross-sectional view taken along a plane passing through the center of the vibration device 10 of FIG. 1 when viewed from the height direction of the vibration device 10. The imaging unit 100 is attached to the front or rear of a vehicle, for example, to capture images of an object. Note that the imaging unit 100 may be attached to a ship, an aircraft, or the like, other than a vehicle.

The imaging unit 100 includes the vibration device 10 and the imaging device 20. The imaging device 20 is housed inside the vibration device 10. The imaging device 20 includes an imaging element such as a CMOS and a CCD, for example. The imaging device 20 can form an image based on light transmitted through the protective cover 11. The imaging unit 100 further includes a base member 21, a main body member 22, and a support member 23. The main body member 22 has a circular plate shape. The base member 21 is located at the center of the upper surface of the main body member 22. The imaging device 20 is fixed on the base member 21. The support member 23 extends upward from the outer periphery of the main body member 22. The vibration device 10 is supported by the support member 23. The imaging unit 100 may include an optical member such as one or more lenses between the protective cover 11 and the imaging device 20.

When the imaging unit 100 is attached to a vehicle or the like and used outdoors, foreign matter such as raindrops, mud, and dust may adhere to the protective cover 11 that covers the imaging device 20, and the protective cover 11 may freeze. The vibration device 10 can generate vibration to remove foreign matter such as raindrops adhering to the protective cover 11 or vibration to prevent freezing.

### 1-1-2. Vibration Circuit

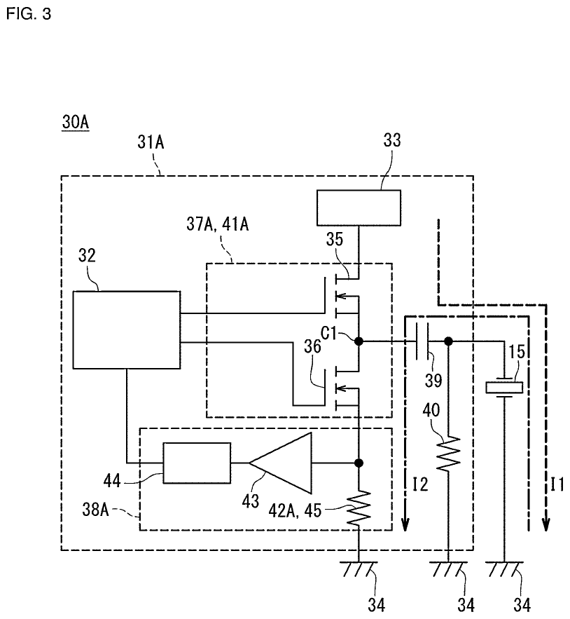

FIG. 3 is a schematic circuit diagram of a vibration circuit 30A including the excitation circuit 31A and the piezoelectric element 15 according to this example embodiment. The excitation circuit 31A includes a control circuit 32, a DC power supply 33, an output circuit 37A including a series circuit of a first switch 35 and a second switch 36, a current detection circuit 38A, a capacitor 39, and a resistor 40.

The control circuit 32 controls switching frequencies of the first switch 35 and the second switch 36. The control circuit 32 includes a general-purpose processor such as a CPU or an MPU that implements predetermined functions by executing programs. The control circuit 32 is configured to be able to communicate with a storage device, and carries out various types of processing in the control circuit 32 or the like, such as switching processing of the first switch 35 and the second switch 36, by calling and executing an arithmetic program and the like stored in the storage device. The control circuit 32 is not limited to a configuration in which hardware resources and software cooperate to realize a predetermined function, but may be a hardware circuit specifically designed to realize a predetermined function. Specifically, the control circuit 32 can be realized by various processors such as GPU, FPGA, DSP, ASIC, or the like, besides CPU and MPU. Such a control circuit 32 may be configured using a signal processing circuit that is a semiconductor integrated circuit, for example.

The DC power supply 33 includes an output end to generate a predetermined voltage between the DC power supply 33 and a reference potential 34. The DC power supply 33 may be a battery, for example, and the output end may be a positive terminal of the battery. Note that the DC power supply 33 may be a known device that can apply a predetermined voltage to the piezoelectric element 15 in combination with the reference potential 34.

The reference potential 34 may be, for example, the ground or body earth connected to a negative terminal of the battery.

The output circuit 37A is connected to the DC power supply 33. As shown in FIG. 3, in this example embodiment, the output circuit 37A is connected to the reference potential 34 through a current-voltage conversion circuit 42A to be described later. The output circuit 37A includes the series circuit of the first switch 35 and the second switch 36 connected to the DC power supply 33, as described above. The series circuit of the first switch 35 and the second switch 36 is also referred to herein as a “first leg 41A”. In the first leg 41A of the output circuit 37A, a connection point C1 between the first switch 35 and the second switch 36 is connected to the piezoelectric element 15 through the capacitor 39.

The first switch 35 is a metal oxide semiconductor field effect transistor (MOSFET), for example, but is not limited thereto. The first switch 35 includes one end (for example, a source) and the other end (for example, a drain). One end of the first switch 35 is connected to the DC power supply 33. The other end of the first switch 35 is connected to the second switch 36. The other end of the first switch 35 is also connected to the piezoelectric element 15 through the capacitor 39. The control circuit 32 is connected to a control end (for example, a gate) of the first switch 35, and can switch the first switch 35 on and off as described above. Specifically, the control circuit 32 can control the first switch 35 to electrically conduct/open the electric path between the DC power supply 33 connected to the first switch 35 and the piezoelectric element 15 by switching the first switch 35 on and off.

As with the first switch 35, the second switch 36 is a MOSFET, for example, but is not limited thereto. The second switch 36 has one end (for example, a source) and the other end (for example, a drain). One end of the second switch 36 is connected to the other end of the first switch 35. Specifically, one end of the second switch 36 is connected to the piezoelectric element 15 through the capacitor 39, as in the case of the other end of the first switch 35. The other end of the second switch 36 is connected to the reference potential 34 through a current-voltage conversion element 45 of the current-voltage conversion circuit 42A. The control circuit 32 is connected to a control end (for example, a gate) of the second switch 36, and can switch the second switch 36 on and off as described above. Specifically, the control circuit 32 can control the second switch 36 to electrically conduct/open the electric path between the piezoelectric element 15 connected to the second switch 36 and the reference potential 34 by switching the second switch 36 on and off.

The current detection circuit 38A can detect at least one of the current flowing through the first switch 35 and the current flowing through the second switch 36, and can output a detection signal indicating the magnitude of the detected current to the control circuit 32. The current detection circuit 38A according to this example embodiment includes the current-voltage conversion circuit 42A, a low pass filter 43, and an analog/digital conversion circuit (AD conversion circuit) 44.

The current-voltage conversion circuit 42A includes the current-voltage conversion element 45. The current-voltage conversion element 45 can convert the current flowing through the current-voltage conversion element 45 into a voltage corresponding to the magnitude of the current flowing through the current-voltage conversion element 45. The current-voltage conversion element 45 may be provided to detect the current flowing through the first switch 35 or the current flowing through the second switch 36, for example, as a voltage. In this example embodiment, the current-voltage conversion element 45 is connected between the second switch 36 and the reference potential 34. The current-voltage conversion element 45 can detect the current flowing from the piezoelectric element 15 to the reference potential 34 through the second switch 36. The current-voltage conversion circuit 42A may have two current-voltage conversion elements and may be configured to have one of the two current-voltage conversion elements detect the current flowing through the first switch 35 and the other of the two current-voltage conversion elements detect the current flowing through the second switch 36. In this example embodiment, the current-voltage conversion element 45 is a resistor (shunt resistor) having a predetermined resistance value. The current-voltage conversion element 45 is not limited to the shunt resistor but may be a Hall element. In this case, the current-voltage conversion element 45 may be disposed near the second switch 36 so as to detect a magnetic field caused by the current flowing through the second switch 36. Therefore, the current-voltage conversion element 45 may be a known element that can convert current into voltage.

The low pass filter 43 is a filter circuit that removes a signal having a frequency component higher than a cutoff frequency. In this example embodiment, the low pass filter 43 is connected to a connection point between the current-voltage conversion element 45 and the second switch 36. The low pass filter 43 smooths the voltage inputted from the current-voltage conversion circuit 42A and outputs the voltage to the AD conversion circuit 44.

The AD conversion circuit 44 is a circuit that converts the voltage (analog signal) smoothed by the low pass filter 43 into a digital signal that can be inputted to the control circuit 32. The AD conversion circuit 44 outputs the digital signal as a detection signal to the control circuit 32. The current detection circuit 38A may be configured to output the voltage smoothed by the low pass filter 43 as the detection signal to the control circuit 32 without including the AD conversion circuit 44.

The current detection circuit 38A according to this example embodiment outputs a detection signal, which is a digital signal generated based on the magnitude of the current flowing through the second switch 36, to the control circuit 32, but is not limited thereto. For example, the current detection circuit 38A may include only the current-voltage conversion circuit 42A and the low pass filter 43, and may be configured to output a detection signal that is an analog signal, instead of a digital signal, to the control circuit 32.

As described above, the piezoelectric element 15 includes the piezoelectric body and the electrode. The piezoelectric element 15 has one end and the other end, and has one end connected to the capacitor 39 and the other end connected to the reference potential 34. Specifically, an electrode on one end side of the piezoelectric element 15 is connected to the capacitor 39, while an electrode on the other end side of the piezoelectric element 15 is connected to the reference potential 34.

The capacitor 39 can store electric charges based on the voltage applied by the DC power supply 33 in a first state to be described later. The capacitor 39 can release the stored charges to the reference potential 34 through the second switch 36 in a second state to be described later. Therefore, in the excitation circuit 31AA, the control circuit 32 controls the switching processing of the first switch 35 and the second switch 36, thus allowing a current I₁ and a current I₂ to flow through the vibration circuit 30A as described later. As described above, the capacitor 39 functions as a polarity inversion circuit to invert the polarity of the voltage applied to the piezoelectric element 15 between the first state and the second state.

The resistor 40 is connected between the connection point between the piezoelectric element 15 and the capacitor 39 and the reference potential 34. Upon completion of the switching processing by the control circuit 32, the one end side and the other end side of the piezoelectric element 15 are at the same potential since the piezoelectric element 15 has one end connected to the reference potential 34 through the resistor 40.

### 1-2. Operation Example

An operation example of the excitation circuit 31A according to the first example embodiment will be described with reference to FIG. 3. As described above, FIG. 3 shows the vibration circuit 30A including the excitation circuit 31A and the piezoelectric element 15.

The control circuit 32 of the excitation circuit 31A according to the first example embodiment executes switching processing to complementarily switch the first switch 35 and the second switch 36 at the switching frequency. Specifically, the control circuit 32 controls the first switch 35 and the second switch 36 to be in a state where the second switch 36 is off when the first switch 35 is on (referred to as a “first state” as appropriate). The control circuit 32 also controls the first switch 35 and the second switch 36 to be in a state where the second switch 36 is on when the first switch 35 is off (referred to as a “second state” as appropriate). The control circuit 32 applies a voltage (for example, a rectangular voltage) having a frequency corresponding to the switching frequency, as a drive signal, to the piezoelectric element 15, based on a predetermined voltage from the DC power supply 33 by complementarily switching the first switch 35 and the second switch 36.

In the first state, the current I₁ flows through the first switch 35 in the vibration circuit 30A. The current I₁ is indicated by the dashed arrow in FIG. 3. As shown in FIG. 3, the current I₁ flows from the DC power supply 33 to the piezoelectric element 15 through the first switch 35. Therefore, a voltage having a high potential on the excitation circuit 31A side is applied to the piezoelectric element 15.

In the vibration circuit 30A, when a voltage is applied to the piezoelectric element 15 in the first state, positive charges are accumulated on the output circuit 37A side and negative charges are accumulated on the reference potential 34 side in the capacitor 39 interposed between the output circuit 37A and the piezoelectric element 15. When the control circuit 32 changes the output circuit 37A from the first state to the second state, the capacitor 39 and the piezoelectric element 15 release the charges. In the second state, the released charges flow as a current I₂ into the vibration circuit 30A through the second switch 36. The current I₂ is indicated by the dashed-dotted arrow in FIG. 3. As shown in FIG. 3, the current I₂ flows from the piezoelectric element 15 to the reference potential 34 through the second switch. In the capacitor 39, negative charges are accumulated on the output circuit 37A side and positive charges are accumulated on the piezoelectric element 15 side. Therefore, a voltage having a low potential on the excitation circuit 31A side is applied to the piezoelectric element 15.

The control circuit 32 can thus apply a voltage whose polarity is inverted at a predetermined frequency to the piezoelectric element 15 by switching the first switch 35 and the second switch 36. Therefore, the vibration circuit 30A according to this example embodiment can reduce the possibility of ion migration occurring in the piezoelectric element 15.

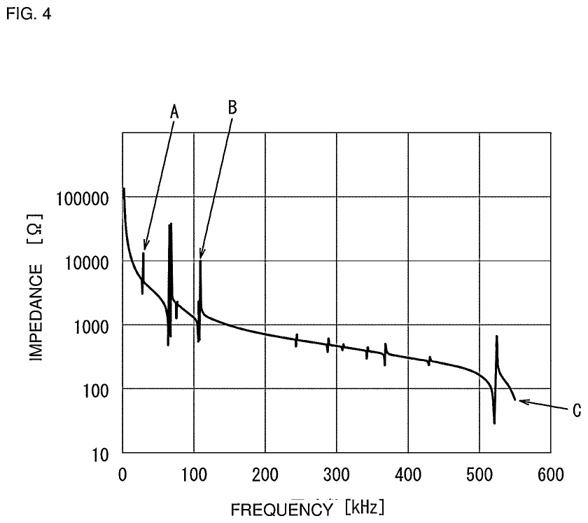

When a drive signal (for example, a rectangular voltage having a predetermined frequency) is applied to the piezoelectric element 15, the impedance of the piezoelectric element 15 changes with the frequency of the drive signal. For example, FIG. 4 is a graph showing the relationship between the frequency of the drive signal applied to the piezoelectric element 15 and the impedance. As shown in FIG. 4, the piezoelectric element 15 has a plurality of frequencies at which the impedance locally decreases. These frequencies correspond to the resonant frequencies of the vibrator 17. In the vibration device 10 according to this example embodiment, the resonant frequencies exist at about 31 kHz (arrow A section), about 110 kHz (arrow B section), and about 550 kHz (arrow C section), for example. When a voltage (drive signal) having a frequency corresponding to any one of these resonant frequencies is applied, the piezoelectric element 15 vibrates the protective cover 11 in a vibration mode that differs for each frequency. For example, when a voltage having a frequency of about 31 kHz is applied, the piezoelectric element 15 vibrates the protective cover 11 using the vibrating body 13 in a first removal mode, which is a vibration mode to vibrate the entire protective cover 11. The first removal mode is a vibration mode capable of atomizing and removing foreign matter such as droplets adhering to the protective cover 11. When a voltage having a frequency of about 110 kHz is applied, the piezoelectric element 15 vibrates the protective cover 11 using the vibrating body 13 in a second removal mode, which is a vibration mode to vibrate the center of the protective cover 11 more than the periphery portion. The vibration in the second removal mode is a vibration corresponding to the resonant frequency of the protective cover 11. When a voltage having a frequency of about 550 kHz is applied, the piezoelectric element 15 vibrates the protective cover 11 using the vibrating body 13 in a de-icing mode, which is a vibration mode that facilitates temperature rise in the protective cover 11. The vibration around about 550 kHz causes the protective cover 11 to vibrate in a higher-order vibration mode with more nodes than the vibration at about 110 kHz. In the de-icing mode, a large amount of electric power is applied to the piezoelectric element 15 since the impedance of the piezoelectric element 15 is small, thus making it possible to quickly raise the temperature of the protective cover 11. The above resonant frequency is just an example, and may be changed depending on the shape, material, and the like of the vibration device 10. The piezoelectric element 15 may be configured to apply vibration to the protective cover 11 in modes other than those described above.

As shown in FIG. 4, when a voltage with a frequency corresponding to the resonant frequency is applied, the impedance of the piezoelectric element 15 becomes locally minimum. Therefore, the control circuit 32 can determine whether the frequency of the voltage applied to the piezoelectric element 15 is the resonant frequency by detecting the value of the current flowing through the piezoelectric element 15.

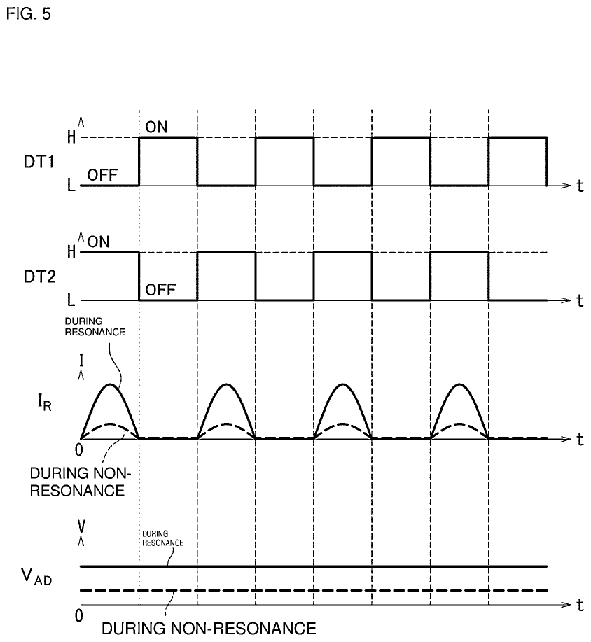

FIG. 5 is a timing chart showing signals inputted to each element of the excitation circuit 31A or signals outputted from each element (for example, a current value and a voltage value). The horizontal axis in FIG. 5 represents time. FIG. 5 shows a signal DT1, a signal DT2, a current I_{R}, and an input voltage V_{AD}. The signal DT1 is an example of a signal for the control circuit 32 to control on and off of the first switch 35. The signal DT2 is an example of a signal for the control circuit 32 to control on and off of the second switch 36. The first switch 35 and the second switch 36 are turned on when the signal DT1 and the signal DT2 are at high level (that is, the first switch 35 electrically connects the DC power supply 33 and the piezoelectric element 15, and the second switch 36 electrically connects the piezoelectric element 15 and the reference potential 34). The first switch 35 and the second switch 36 are turned off when the signal DT1 and the signal DT2 are at low level (that is, the first switch 35 electrically opens the DC power supply 33 and the piezoelectric element 15, and the second switch 36 electrically opens the piezoelectric element 15 and the reference potential 34). The current I_{R} represents a current flowing through the current-voltage conversion element 45. The current I_{R} corresponds to a voltage inputted to the low pass filter 43 based on the current-voltage conversion circuit 42A. The input voltage V_{AD} represents a smoothed voltage inputted from the low pass filter 43 to the AD conversion circuit 44. As shown in FIG. 5, V_{AD} is a signal having a DC component in this example embodiment.

FIG. 5 shows a plurality of waveforms of the current I_{R}. The current I_{R} indicated by the solid line is an example of the waveform of the current flowing through the current-voltage conversion element 45 when the switching frequency of the first switch 35 and the second switch 36 corresponds to the resonant frequency of the vibrator 17 (that is, during resonance). The current I_{R} indicated by the dashed line is an example of the waveform of the current flowing through the current-voltage conversion element 45 when the switching frequency of the first switch 35 and the second switch 36 does not correspond to the resonant frequency of the vibrator 17 (that is, during non-resonance). As is clear from FIG. 5, the current during resonance is larger than the current during non-resonance.

Similarly, FIG. 5 shows a plurality of waveforms of the input voltage V_{AD}. The input voltage V_{AD} indicated by the solid line is an example of the waveform of the voltage that is outputted from the low pass filter 43 and inputted to the AD conversion circuit 44 during resonance. The input voltage V_{AD} indicated by the dashed line is an example of the waveform of the voltage that is outputted from the low pass filter 43 and inputted to the AD conversion circuit 44 during non-resonance. As is clear from FIG. 5, the input voltage during resonance is larger than the input voltage during non-resonance.

Therefore, the signal (voltage) inputted to the AD conversion circuit 44 has a larger value during resonance than during non-resonance. Therefore, the detection signal inputted from the AD conversion circuit 44 to the control circuit 32 similarly has a larger value during resonance than during non-resonance. Therefore, the control circuit 32 can determine whether the switching frequency of the first switch 35 and the second switch 36, that is, the frequency of the drive signal inputted to the piezoelectric element 15 is the resonant frequency, based on the detection signal inputted from the AD conversion circuit 44. For example, the control circuit 32 acquires the value of the detection signal inputted from the AD conversion circuit 44 at two or more switching frequencies when the switches 35 and 36 are each operated at a specific switching frequency. The control circuit 32 can then compare the values of the detection signals at different switching frequencies and determine that the switching frequency corresponding to the detection signal with the larger value is closer to the resonant frequency. Therefore, the control circuit 32 switches each of the switches 35 and 36 at a plurality of switching frequencies within a predetermined frequency range, and compares the values of a plurality of detection signals corresponding to the plurality of switching frequencies. The control circuit 32 can thus determine the switching frequency closest to the resonant frequency within the predetermined frequency range.

Although periods of the signal DT1 and the signal DT2 are different between resonance and non-resonance, FIG. 5 shows, for simplicity, the signal waveforms with the same width even if the periods are different. Therefore, the period during which the current I_{R} flows actually differs between resonance and non-resonance.

The control circuit 32 can thus acquire the current flowing through the current-voltage conversion element 45 of the current-voltage conversion circuit 42A as a DC component based on the switching processing. Therefore, unlike the case of detecting the current flowing through the piezoelectric element 15, the control circuit 32 does not need to set the sampling frequency for current detection sufficiently higher than the resonant frequency of the vibrator 17. This can reduce the cost for the current-voltage conversion circuit 42A. By detecting the current, the control circuit 32 can calculate the impedance of the piezoelectric element 15 and can determine the resonant frequency of the vibrator 17.

As described above, the control circuit 32 can determine the resonant frequency of the vibrator 17 based on the value of the detection signal inputted from the current detection circuit 38A by controlling the switching frequency and changing the frequency of the voltage applied to the piezoelectric element 15. For example, the control circuit 32 can determine the resonant frequency of the vibrator 17 using more than one method. The excitation circuit 31A according to this example embodiment has three sweep methods: a first sweep method, a second sweep method, and a third sweep method (to be described in detail later). The first sweep method, the second sweep method, and the third sweep method differ in how to change the switching frequency to determine the resonant frequency of the vibrator 17. The control circuit 32 has a plurality of sequences executed in each of the first to third sweep methods. In this example embodiment, the plurality of sequences include a search mode and a drive mode.

In the search mode, the control circuit 32 determines the resonant frequency by changing the switching frequency within a predetermined frequency range (hereinafter referred to as a “first frequency range”). Hereinafter, the process in which the control circuit 32 changes the switching frequency by a predetermined increment (or decrement) within an arbitrary frequency range in order to determine the resonant frequency is also referred to as “sweep”. As described above, the control circuit 32 can determine the switching frequency at which the detection signal outputted from the AD conversion circuit 44 has the largest value to be the resonant frequency. Therefore, if the resonant frequency is within the first frequency range, the control circuit 32 can determine the resonant frequency. When the detection signal outputted from the AD conversion circuit 44 has the largest value at the upper limit frequency within the first frequency range, there is a possibility that the switching frequency is not the resonant frequency. Therefore, in such a case, the control circuit 32 may change the first frequency range to include a higher frequency, change the switching frequency within the range, and determine the resonant frequency again. Similarly, when the detection signal outputted from the AD conversion circuit 44 has the largest value at the lower limit frequency within the first frequency range, the control circuit 32 may change the first frequency range to include a lower frequency and determine the resonant frequency again. When determining that there are a plurality of switching frequencies at which the value of the outputted detection signal becomes locally the largest, the control circuit 32 may perform the sweep again.

When determining the resonant frequency by the search mode, the control circuit 32 can perform switching at the frequency to vibrate the protective cover 11 in a predetermined vibration mode (for example, the first removal mode, the second removal mode, or the de-icing mode) corresponding to the frequency. However, the resonant frequency may vary due to various factors. For example, the resonant frequency may vary depending on the temperature change of the protective cover 11. The resonant frequency may also change when foreign matter adheres to the protective cover 11. Therefore, the excitation circuit 31A according to this example embodiment is configured to respond to changes in the frequency in the drive mode.

In the drive mode, the control circuit 32 changes the switching frequency within a predetermined frequency range (hereinafter referred to as a “second frequency range”) narrower than the first frequency range and determines the resonant frequency. When shifting from the search mode to the drive mode, the control circuit 32 sets the second frequency range centered on the resonant frequency determined in the search mode, and changes the switching frequency within the second frequency range. The control circuit 32 sweeps the switching frequency within the second frequency range, determines the switching frequency with the largest value of the detection signal outputted from the AD conversion circuit 44, and determines that the determined switching frequency is the current resonant frequency of the vibrator 17. After determining the current resonant frequency of the vibrator 17, the control circuit 32 updates the second frequency range by changing the frequency set at the center of the second frequency range to the current resonant frequency. The control circuit 32 sweeps the switching frequency again within the updated second frequency range and repeats the update of the second frequency range described above. By operating in such a drive mode, the control circuit 32 can make the switching frequency follow the resonant frequency even if the resonant frequency of the vibrator 17 changes.

When the piezoelectric element 15 is vibrated, there is a case where the resonant frequency of the vibrator 17 does not match when changing from the low frequency side to the high frequency side and when changing from the high frequency side to the low frequency side. Therefore, the control circuit 32 of the excitation circuit 31A according to this example embodiment is configured to sweep the switching frequency using a plurality of methods when determining the resonant frequency using the search mode or drive mode. In this example embodiment, as described above, the control circuit 32 has the first sweep method, the second sweep method, and the third sweep method. In the first sweep method, the control circuit 32 changes the switching frequency from the low frequency side to the high frequency side (hereinafter also referred to as “upward sweep”). In the second sweep method, the control circuit 32 changes the switching frequency from the low frequency side to the high frequency side and further from the high frequency side to the low frequency side (hereinafter also referred to as “upward and downward sweep”). In the third sweep method, the control circuit 32 changes the switching frequency from the high frequency side to the low frequency side (hereinafter also referred to as “downward sweep”).

The excitation circuit 31A according to this example embodiment is configured to operate the protective cover 11 in a predetermined vibration mode by matching the switching frequency of the first switch 35 and the second switch 36 with the resonant frequency of the vibrator 17. Even when the first switch 35 and the second switch 36 are operated at a switching frequency that has a predetermined ratio to the resonant frequency, the impedance is locally reduced or minimized. Here, the frequency having a predetermined ratio is a frequency 1/(2n+1) times the resonant frequency (n is a positive integer).

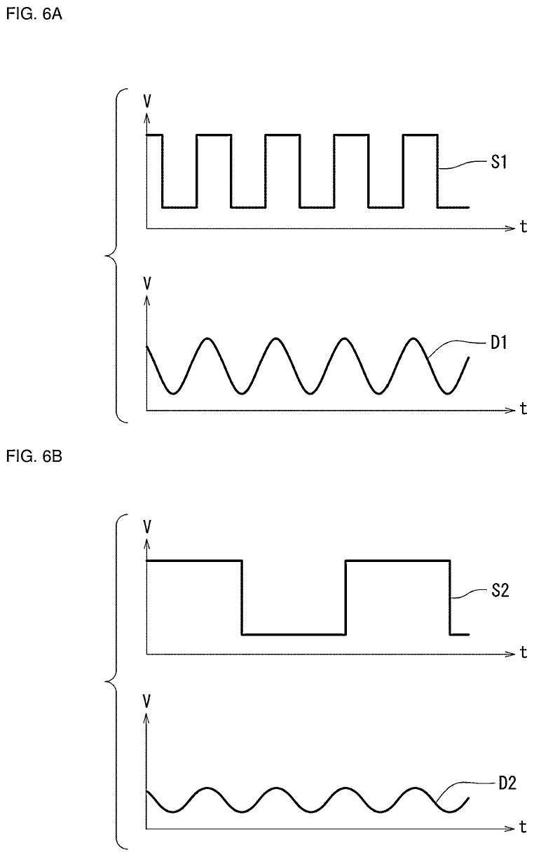

FIG. 6A is a graph showing a temporal change in a drive signal (voltage) having a frequency of 31.5 kHz, which is a frequency near one of the resonant frequencies, applied to the piezoelectric element 15, and a temporal change in displacement amount of the protective cover 11 when the piezoelectric element 15 is driven at that frequency. In FIG. 6A, a waveform S1 indicates the temporal change in the drive signal, and a waveform D1 indicates the temporal change in the displacement amount. The displacement amount of the protective cover 11 can be obtained by measuring the displacement of the protective cover 11 using a laser Doppler meter, for example, and the waveform D1 in FIG. 6A indicates a temporal change in a voltage value obtained by converting the measured displacement amount into voltage. In the graph shown in FIG. 6A, the horizontal axis represents time and the vertical axis represents voltage.

FIG. 6B is a graph showing a temporal change in a drive signal having a frequency of 10.5 kHz, which is ⅓ times the frequency of 31.5 kHz, applied to the piezoelectric element 15, and a temporal change in displacement amount of the protective cover 11 when the piezoelectric element 15 is driven at that frequency. In FIG. 6B, a waveform S2 indicates the temporal change in the drive signal, and a waveform D2 indicates the temporal change in the displacement amount. In the graph shown in FIG. 6B, the horizontal axis represents time and the vertical axis represents voltage.

As can be seen from FIGS. 6A and 6B, even when the frequency of the drive signal is ⅓ times the resonant frequency, the frequency of displacement of the protective cover 11 (that is, the frequency of vibration of the protective cover 11) is equal to the resonant frequency. As can be seen from FIGS. 6A and 6B, the maximum displacement amount when the piezoelectric element 15 is driven at a frequency that is ⅓ times the resonant frequency is about ⅓ times the maximum displacement amount when the piezoelectric element 15 is driven at the resonant frequency. The above relationship holds true when the frequency of the drive signal is 1/(2n+1) times the resonant frequency (n is a positive integer). In other words, when the frequency of the drive signal is 1/(2n+1) times the resonant frequency, the maximum displacement amount of the protective cover 11 is about 1/(2n+1) times the maximum displacement amount when the piezoelectric element 15 is driven at the resonant frequency. By utilizing such changes in the displacement amount based on the difference in the frequency of the drive signal, the vibration device 10 according to this example embodiment can obtain various effects.

For example, in the search mode, the control circuit 32 can determine the frequency corresponding to the resonant frequency by sweeping the switching frequency in a first frequency range that includes a frequency equivalent to 1/3 times the resonant frequency. The control circuit 32 determines a frequency three times the switching frequency determined to correspond to the resonant frequency as the resonant frequency, defines a second frequency range centered around the frequency three times the switching frequency, and executes the drive mode. The control circuit 32 can thus reduce the power consumption necessary for the determination while reducing or preventing the temperature increase of the piezoelectric element 15. The control circuit 32 can also reduce or prevent vibrations that occur when executing the search mode by lowering the current value, and can reduce or prevent fluctuations in the resonant frequency due to changes in the state of foreign matter or the like due to the vibrations.

The above relationship also holds true between the resonant frequency and a frequency 2n+1 times the resonant frequency (n is a positive integer). For example, when the control circuit 32 applies a drive signal having a frequency three times the resonant frequency to the piezoelectric element 15, the temporal change in the displacement amount of the protective cover 11 has a frequency corresponding to the resonant frequency, as in the case of FIG. 6A. The maximum value of the displacement amount of the protective cover 11 is about ⅓ times the maximum value of the displacement amount when a drive signal having the resonant frequency is applied. Therefore, in order to reduce or prevent the temperature increase of the piezoelectric element 15, the control circuit 32 may operate by setting the switching frequency to switch on and off of the first switch 35 and the second switch 36 to (2n+1) times the resonant frequency.

The control circuit 32 determines whether foreign matter adheres to the protective cover 11 by combining changes in the resonant frequency and changes in impedance. The resonant frequency of the vibrator 17 decreases as the temperature increases. Similarly, the minimum impedance (local minimum value of impedance) of the piezoelectric element 15 decreases as the temperature increases. On the other hand, when foreign matter (for example, water) adheres to the protective cover 11, the resonant frequency of the vibrator 17 decreases as the amount of adhering water increases. The rate of change in the minimum impedance of the piezoelectric element 15 increases as the amount of adhering water increases. The control circuit 32 can thus determine whether foreign matter adheres to the protective cover 11 by referring to the change in temperature and the change in minimum impedance. Note that the change in temperature may be acquired by a temperature sensor that may be provided in the vibration device 10, for example. The control circuit 32 may drive the piezoelectric element 15 at a frequency 1/(2n+1) times the resonant frequency (n is a positive integer) in the search mode as described above until the foreign matter adheres. Once it is determined that there is foreign matter adhering to the protective cover, the control circuit 32 may drive the piezoelectric element 15 at the resonant frequency by switching to the drive mode. The control circuit 32 can reduce the power consumption of the vibration device 10 by driving the piezoelectric element 15 as described above.

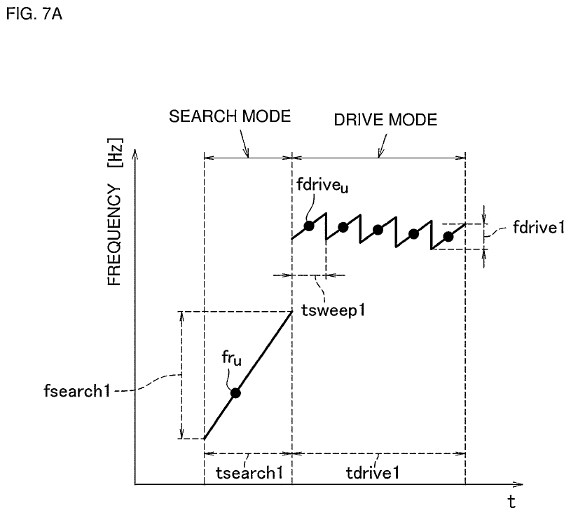

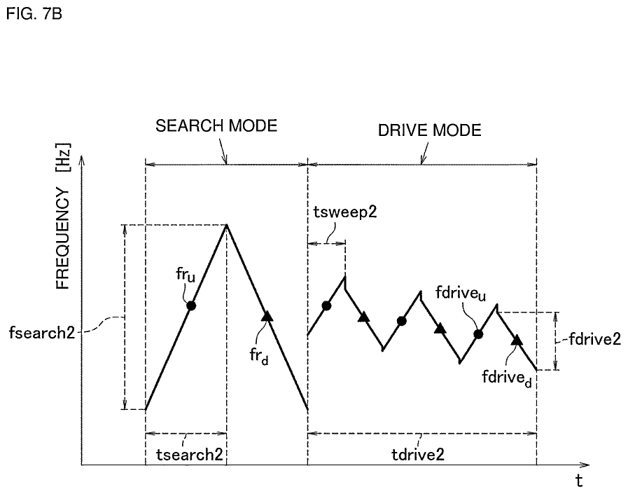

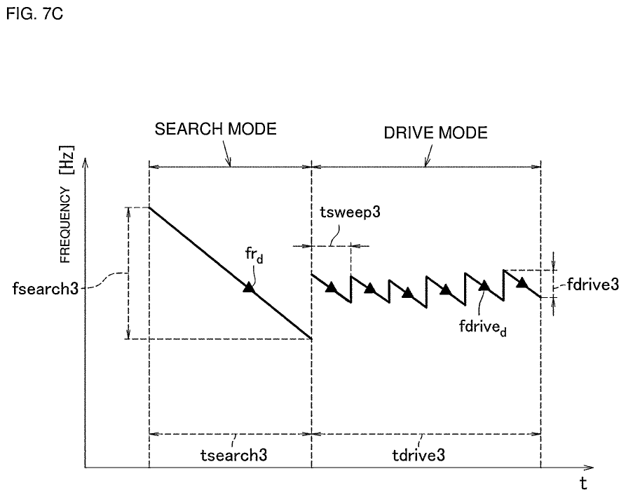

FIG. 7A shows an example of control by the first sweep method for the control circuit 32 to determine the resonant frequency. FIG. 7B shows an example of control by the second sweep method for the control circuit 32 to determine the resonant frequency. FIG. 7C shows an example of control by the third sweep method for the control circuit 32 to determine the resonant frequency.

FIG. 7A shows an example of search mode and drive mode processing by the control circuit 32 using the first sweep method.

In this example embodiment, the control circuit 32 sets the first frequency range to include a frequency about ⅓ times the resonant frequency, and executes the search mode. In FIG. 7A, fsearch1 denotes the first frequency range. The control circuit 32 sweeps upward the switching frequency to determine a frequency frᵤ at which the current reaches its maximum within the first frequency range, and then multiplies the value of the frequency frᵤ by three to obtain fdriveᵤ. As shown in FIG. 7A, the control circuit 32 executes the sweep in a period tsearch1.

The control circuit 32 sets the second frequency range so that the calculated fdriveᵤ is centered, and executes the drive mode. In FIG. 7A, fdrive1 denotes the second frequency range. The control circuit 32 sweeps upward the switching frequency within the second frequency range, determines the frequency at which the current value reaches its maximum, and updates fdriveᵤ to the frequency. As shown in FIG. 7A, the control circuit 32 executes the sweep in the second frequency range in a period tsweep1. Then, the control circuit 32 updates the second frequency range every time it executes the sweep, and again executes the sweep in the updated second frequency range in the period tsweep1. The period tdrive1 indicates a period in which the piezoelectric element 15 is driven in the drive mode. By operating as described above, the control circuit 32 can vibrate the protective cover 11 at a more accurate frequency while following the changing resonant frequency. After driving the piezoelectric element 15 in the drive mode for a predetermined period, such as the period tdrive1, for example, the control circuit 32 may switch to driving the piezoelectric element 15 in the search mode again. The control circuit 32 may also switch from driving in the drive mode to driving in the search mode when determining that the adhesion of foreign matter is eliminated based on a change in temperature and a change in impedance, for example. The control circuit 32 may stop driving the piezoelectric element, instead of switching from the drive mode to the search mode. The same applies to the second sweep method and the third sweep method to be described later.

FIG. 7B shows an example of search mode and drive mode processing by the control circuit 32 using the second sweep method.

In this example embodiment, the control circuit 32 sets the first frequency range to include the frequency corresponding to the resonant frequency, and executes the search mode. In FIG. 7B, fsearch2 denotes the first frequency range. The control circuit 32 sweeps upward the switching frequency to determine a frequency frᵤ at which the current reaches its maximum within the first frequency range, and then determines fdrive ᵤ based on the frequency frᵤ. The control circuit 32 sets an upward second frequency range to be centered around the determined fdriveᵤ. The control circuit 32 also sweeps downward the switching frequency to determine a frequency fr_{d} at which the current reaches its maximum within the first frequency range, and then determines fdrive_{d} based on the frequency fr_{d}. The control circuit 32 sets a downward second frequency range to be centered around the determined fdrive_{d}. As shown in FIG. 7B, the control circuit 32 executes an upward sweep and a downward sweep in a period tsearch2. Note that the period tsearch2 for the upward sweep and the period tsearch2 for the downward sweep may have the same length or different lengths.

Once the upward and downward second frequency ranges are set, the control circuit 32 executes the drive mode. The control circuit 32 sweeps the switching frequency upward and downward within each second frequency range to determine the frequency at which the current value reaches its maximum, and updates fdriveᵤ and fdrive_{d} to each frequency. As shown in FIG. 7B, the control circuit 32 executes the upward sweep and downward sweep within the second frequency range in a period tsweep2. Then, the control circuit 32 updates each second frequency range every time it executes the upward sweep or downward sweep, and again executes a sweep within the updated second frequency range in the period tsweep2. A period tdrive2 indicates a period during which the piezoelectric element 15 is driven in the drive mode. By operating as described above, the control circuit 32 can vibrate the protective cover 11 at a more accurate frequency while following the changing resonant frequency for each of the upward sweep and the downward sweep.

FIG. 7C shows an example of search mode and drive mode processing by the control circuit 32 using the third sweep method.

In this example embodiment, the control circuit 32 sets the first frequency range to include the frequency corresponding to the resonant frequency, and executes the search mode. In FIG. 7C, fsearch3 denotes the first frequency range. The control circuit 32 sweeps downward the switching frequency to determine a frequency fr_{d} at which the current reaches its maximum within the first frequency range, and then determines fdrive_{d} based on the frequency fr_{d}. As shown in FIG. 7C, the control circuit 32 executes a sweep in a period tsearch3.

The control circuit 32 sets the second frequency range to be centered around the determined fdrive_{d}, and executes the drive mode. In FIG. 7C, fdrive3 denotes the second frequency range. The control circuit 32 sweeps downward the switching frequency downward within the second frequency range to determine a frequency at which the current value reaches its maximum, and updates fdrive_{d} to the frequency. As shown in FIG. 7C, the control circuit 32 executes a sweep within the second frequency range in a period tsweep3. Then, the control circuit 32 updates the second frequency range every time it executes the sweep, and again executes the sweep within the updated second frequency range in the period tsweep3. A period tdrive3 indicates a period during which the piezoelectric element 15 is driven in the drive mode. By operating as described above, the control circuit 32 can vibrate the protective cover 11 at a more accurate frequency while following the changing resonant frequency.

For example, the control circuit 32 can use the first sweep method described above in the first removal mode. The control circuit 32 can also use the second sweep method described above in the second removal mode. The control circuit 32 can also use the third sweep method described above in the de-icing mode.

The sweep method used in each vibration mode is not limited to the above, and the control circuit 32 may vibrate the piezoelectric element 15 in any combination. In the first sweep method described above, the control circuit 32 drives the piezoelectric element 15 using a frequency that is ⅓ of the resonant frequency in the search mode, and drives the piezoelectric element 15 using the resonant frequency in the drive mode. However, the present disclosure is not limited thereto. In the second sweep method and the third sweep method described above, the control circuit 32 drives the piezoelectric element 15 using the resonant frequency in the search mode and drive mode, but the present disclosure is not limited thereto. For example, the control circuit 32 may use at least one of the first to third sweep methods to drive the piezoelectric element 15 using the resonant frequency in the search mode and the drive mode. The control circuit 32 may also use at least one of the first to third sweep methods to drive the piezoelectric element 15 using a frequency 1/(2n+1) times the resonant frequency in the search mode and drive the piezoelectric element 15 using the resonant frequency in the drive mode. The control circuit 32 may also use at least one of the first to third sweep methods to drive the piezoelectric element 15 using the resonant frequency in the search mode and drive the piezoelectric element 15 using a frequency 1/(2n+1) times the resonant frequency in the drive mode. The control circuit 32 may also use at least one of the first to third sweep methods to drive the piezoelectric element 15 using a frequency 1/(2n+1) times the resonant frequency in the search mode and the drive mode.

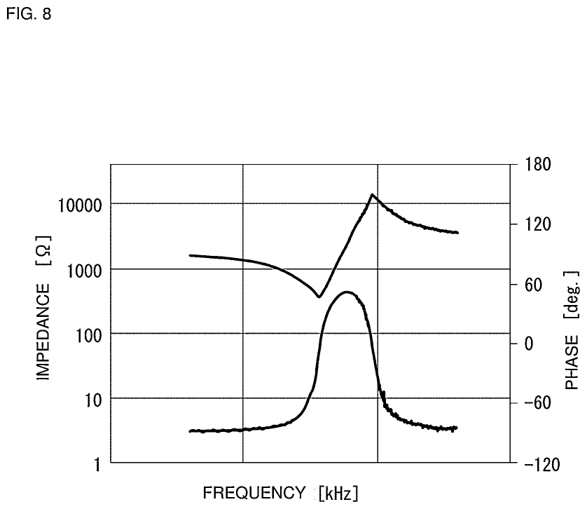

FIG. 8 is a graph showing the impedance of the piezoelectric element 15 with respect to the switching frequency near a certain resonant frequency and a phase difference between the voltage applied to the piezoelectric element 15 and the current flowing through the piezoelectric element 15. As shown in FIG. 8, when the switching frequency changes around the resonant frequency, the impedance changes. As described above, the frequency at which the impedance is locally reduced or minimized corresponds to the resonant frequency. As shown in FIG. 8, when the switching frequency changes near the resonant frequency, the phase difference between the voltage applied to the piezoelectric element 15 and the current flowing through the piezoelectric element changes. When the control circuit 32 switches the first switch 35 and the second switch 36 at the resonant frequency, the phase difference becomes zero. Therefore, by configuring the excitation circuit 31A to detect this phase difference, the switching frequency corresponding to the resonant frequency can be determined more accurately.

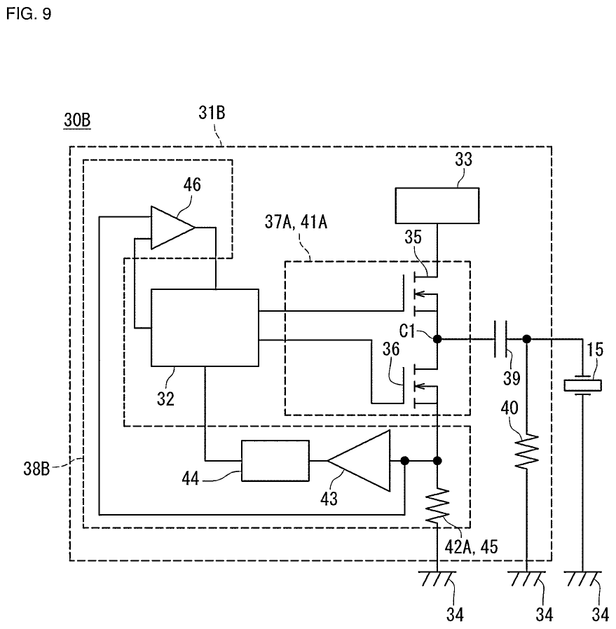

FIG. 9 shows a modification of the excitation circuit 31A according to the first example embodiment. FIG. 9 shows a vibration circuit 30B. The vibration circuit 30B includes an excitation circuit 31B and a piezoelectric element 15. The excitation circuit 31B further includes a phase comparator 46, compared to the excitation circuit 31A. The excitation circuit 31B is configured such that the phase comparator 46 can compare the phase difference between the voltage applied to the piezoelectric element 15 and the current flowing through the piezoelectric element, as described above.

The phase comparator 46 is a multiplier, for example. The phase comparator 46 can detect a voltage based on the current flowing through the current-voltage conversion element 45. The phase related to the current used by the phase comparator 46 is the current flowing through the current-voltage conversion element 45 when the second switch 36 is on. The control circuit 32 can also output a control signal to switch the first switch 35 and the second switch 36 to the phase comparator 46. Therefore, the phase comparator 46 can compare the phase of the voltage applied to the piezoelectric element 15 and the phase of the current flowing through the piezoelectric element, based on the phase of the control signal. For example, the phase comparator 46 may be configured to compare the phase of the control signal to drive the second switch 36 with the phase of the voltage based on the current flowing through the current-voltage conversion element 45, and to output a predetermined signal (for example, voltage) to the control circuit 32 when there is a difference in phase. The phase comparator 46 may output a voltage having a positive value when the phase of the control signal is ahead of the phase of the voltage based on the current flowing through the current-voltage conversion element 45, and may output a voltage having a negative value when the phase is delayed to the control circuit 32. With this configuration, the control circuit 32 can detect if there is a phase difference between the current and voltage in the piezoelectric element 15, based on the signal outputted from the phase comparator 46. The control circuit 32 can also detect whether the phase of the current is ahead of or behind the voltage. As can be seen from FIG. 9, when the switching frequency is near the resonant frequency, advance or delay of the phase between the voltage applied to the piezoelectric element 15 and the current flowing through the piezoelectric element 15 depends on whether the switching frequency is higher than or lower than the resonant frequency. Therefore, the control circuit 32 can determine based on the phase difference whether the switching frequency needs to be changed to the high frequency side or the low frequency side, in order to match the switching frequency with the resonant frequency. The control circuit 32 can more appropriately match the switching frequency with the resonant frequency of the vibrator 17 by controlling the switching frequency based on the phase difference detected by the phase comparator 46. Contrary to the above, the phase comparator 46 may output a voltage having a negative value when the phase of the control signal is ahead of the phase of the voltage based on the current flowing through the current-voltage conversion element 45, and may when it is delayed, and may output a voltage having a positive value when the phase is delayed to the control circuit 32.

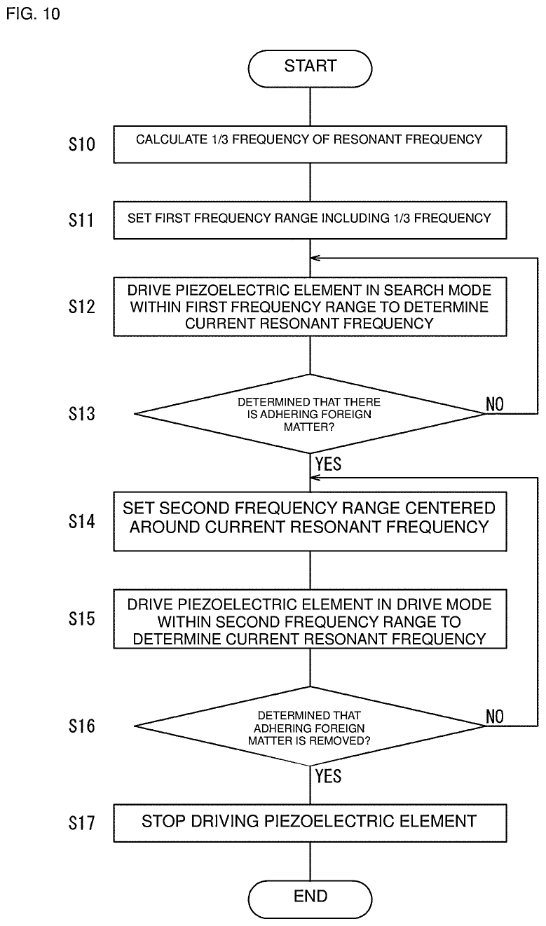

Next, vibration processing of the vibration device 10 by the control circuit 32 will be described based on a flowchart. FIG. 10 is a flowchart for explaining the vibration processing of the vibration device 10 by the control circuit 32 of the excitation circuit 31A according to this example embodiment. In the vibration processing, the control circuit 32 executes the search mode within the first frequency range including the frequency that is 1/3 of the resonant frequency to drive the piezoelectric element 15. When determining that there is adhering foreign matter to the protective cover 11, the control circuit 32 determines the current resonant frequency and executes the drive mode within the second frequency range including the current resonant frequency to drive the piezoelectric element 15.

First, the control circuit 32 calculates a frequency that is ⅓ times the resonant frequency of the vibration mode for driving the piezoelectric element 15 (S10). After calculating the ⅓ frequency, the control circuit 32 sets a first frequency range including the calculated frequency (S11). After setting the first frequency range, the control circuit 32 drives the piezoelectric element 15 within the first frequency range in the search mode and determines the current resonant frequency (S12). Specifically, the control circuit 32 sweeps the switching frequency of the first switch 35 and the second switch 36 within the first frequency range to determine the current resonant frequency based on the magnitude of the current detected by the current detection circuit 38A.

The control circuit 32 determines whether there is foreign matter adhering to the protective cover 11, based on the impedance calculated from the magnitude of the detected current, for example, as described above (S13). When determining that there is no adhering foreign matter (S13: No), the control circuit 32 executes step S12 again to determine the current resonant frequency again. When determining that there is adhering foreign matter (S13: Yes), the control circuit 32 sets a second frequency range centered on the current resonant frequency at this point (S14). After setting the second frequency range, the control circuit 32 drives the piezoelectric element 15 within the second frequency range in the drive mode, and determines the current resonant frequency (S15). Specifically, the control circuit 32 sweeps the switching frequency of the first switch 35 and the second switch 36 within the second frequency range to determine the current resonant frequency based on the magnitude of the current detected by the current detection circuit 38A.

As in step S13, the control circuit 32 checks if there is any foreign matter remaining on the protective cover 11, based on the impedance calculated from the magnitude of the detected current, for example (S16). When determining that there is foreign matter remaining on the protective cover 11 (S16: No), the control circuit 32 executes step S14 again to set a second frequency range centered on the current resonant frequency determined in step S15. Specifically, the control circuit 32 updates the second frequency range to a range centered on the current resonant frequency. The control circuit 32 then drives the piezoelectric element 15 in the drive mode until the adhering foreign matter is removed. When determining that the adhering foreign matter is removed (that is, there is no more foreign matter adhering to the protective cover 11) (S16: Yes), the control circuit 32 stops driving the piezoelectric element 15 (S17). The control circuit 32 can thus remove foreign matter adhering to the protective cover 11. The control circuit 32 can also reduce the power required to remove foreign matter.

As shown in FIG. 8, the impedance value of the piezoelectric element 15 at each resonant frequency corresponding to each vibration mode varies with the frequency. Therefore, the current value flowing through the piezoelectric element 15 when the first switch 35 and the second switch 36 are switched depending on each resonant frequency varies with the frequency. Therefore, the current detection circuit 38A needs to be configured to correspond to the vibration mode in which the current flowing through the current-voltage conversion element 45 reaches its maximum (that is, the impedance value of the piezoelectric element 15 reaches its minimum).

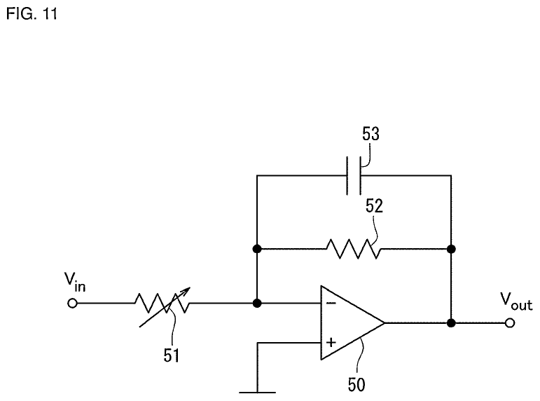

FIG. 11 is a schematic circuit diagram showing an example of a low pass filter 43 configured to be able to switch an amplification factor. The low pass filter 43 can change the amplification factor for the input voltage, and thus can determine the resonant frequency even with varying magnitude of the current flowing through the current-voltage conversion element 45.

The low pass filter 43 includes an operational amplifier 50, a variable resistor 51, a resistor 52, and a capacitor 53.

The operational amplifier 50 includes an inverting input terminal connected to an input end (that is, an end different from the reference potential side of the current-voltage conversion element 45) Vin through the variable resistor 51. The operational amplifier 50 also includes a non-inverting input terminal connected to the reference potential and an output terminal connected to an output end (that is, an end for output to the AD conversion circuit 44) Vout. The variable resistor 51 is disposed between the input terminal Vin and the inverting input terminal of the operational amplifier 50. The resistor 52 is disposed so as to connect the inverting input terminal and the output terminal of the operational amplifier through the resistor 52. The capacitor 53 is disposed in parallel with the resistor 52 so as to connect the inverting input terminal and the output terminal of the operational amplifier 50 through the capacitor 53. By changing the resistance value of the variable resistor 51, the low pass filter 43 can change the amplification factor (that is, gain) for the voltage inputted from the input terminal Vin. Therefore, the resonant frequency can be determined even with varying magnitude of the current flowing through the current-voltage conversion element 45. The frequency control circuit 32 can change the amplification factor based on the vibration mode to vibrate the piezoelectric element 15, for example. The control circuit 32 may also change the amplification factor based on the frequency included in the first frequency range for driving the piezoelectric element 15 in the search mode. By including the low pass filter 43 having such a configuration, the excitation circuit 31B can accurately detect the peak current in a plurality of vibration modes having different peak currents.

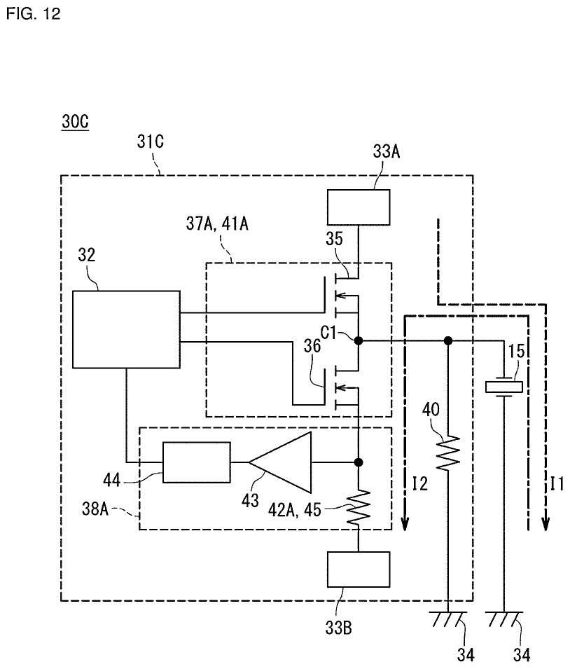

FIG. 12 shows a modification of the excitation circuit 31A according to the first example embodiment. FIG. 12 shows a configuration of a vibration circuit 30C. The vibration circuit 30C includes an excitation circuit 31C and a piezoelectric element 15. The excitation circuit 31C includes a DC power supply 33A and a negative power supply circuit 33B, in place of the DC power supply 33, compared to the excitation circuit 31A. The excitation circuit 31C does not include the capacitor 39 compared to the excitation circuit 31A. The negative power supply circuit 33B functions as a polarity inversion circuit, instead of the capacitor 39 in the excitation circuit 31A.

In this example embodiment, the DC power supply 33A is connected to the first switch 35, instead of the DC power supply 33 in the excitation circuit 31A. The DC power supply 33A outputs a positive voltage. The negative power supply circuit 33B is connected to the series circuit of the output circuit 37A on the opposite side to the DC power supply 33A. Specifically, the negative power supply circuit 33B is connected to the second switch 36, instead of the reference potential 34 in the vibration circuit 30A, through the current-voltage conversion circuit 42A. The negative power supply circuit 33B outputs a negative voltage. Specifically, the negative power supply circuit 33B has a potential whose polarity is inverted with respect to the DC power supply 33A based on the potential of the reference potential 34. For example, when the potential of the reference potential 34 is zero and the potential of the DC power supply 33A is +Vp, the potential of the negative power supply circuit 33B may be −Vp. The DC power supply 33A and the negative power supply circuit 33B may each be a known device capable of applying a predetermined voltage to the piezoelectric element 15 in combination with the reference potential.

With such a configuration, when the control circuit 32 executes the switching processing of the first switch 35 and the second switch 36, a voltage whose polarity is inverted between the first state and the second state can be applied to the piezoelectric element 15. For example, when the potential of the reference potential 34 is zero, the potential of the DC power supply 33A is +Vp, and the potential of the negative power supply circuit 33B is −Vp, the control circuit 32 can apply a positive voltage of +Vp to the piezoelectric element 15 in the first state and can apply a negative voltage of −Vp to the piezoelectric element 15 in the second state. In this case, the control circuit 32 can apply a voltage that becomes zero on average to the piezoelectric element 15 by the switching processing. By applying a voltage with inverted polarity to the piezoelectric element 15, the vibration circuit 30C can reduce the possibility of ion migration occurring in the piezoelectric element 15, as in the case of the vibration circuit 30A.

### Second Example Embodiment

### 2-1. Configuration Example

A vibration device according to a second example embodiment of the present disclosure will be described. Note that differences from the first example embodiment will be mainly described in the second example embodiment. In the second example embodiment, the same or equivalent configurations as those in the first example embodiment will be described with the same reference numerals. In the second example embodiment, overlapping descriptions with the first example embodiment will be omitted.

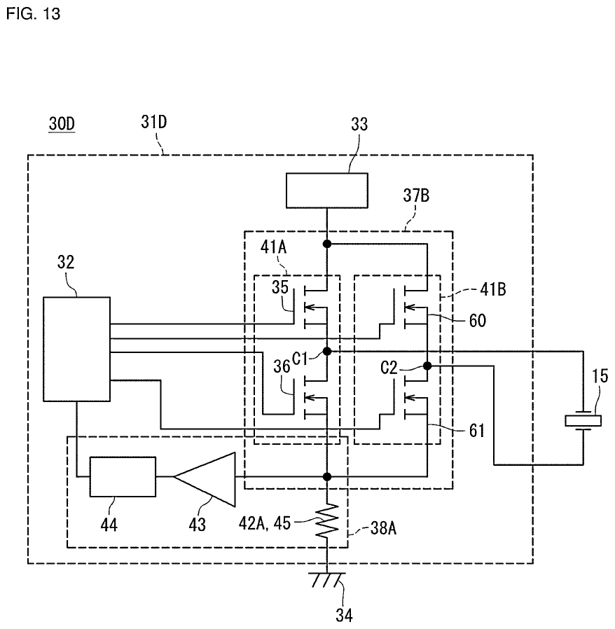

FIG. 13 is a schematic circuit diagram of a vibration circuit 30D including an excitation circuit 31D and a piezoelectric element 15 according to the second example embodiment of the present disclosure. The excitation circuit 31D of the vibration circuit 30D has an output circuit 37B further including a series circuit of a third switch 60 and a fourth switch 61 connected to the DC power supply 33, instead of the output circuit 37A of the excitation circuit 31A. The series circuit of the third switch 60 and the fourth switch 61 is also referred to as a “second leg 41B” in this specification. The second leg 41B is connected in parallel with the first leg 41A between the DC power supply 33 and the reference potential 34. As shown in FIG. 13, the second leg 41B is connected to the reference potential 34 through the current-voltage conversion element 45 of the current-voltage conversion circuit 42A in this example embodiment. Alternatively or additionally, the second leg 41B may be connected to the DC power supply 33 through the current-voltage conversion element 45 of the current-voltage conversion circuit 42A. As can be seen from FIG. 13, the piezoelectric element 15 of the vibration circuit 30D is not connected to the reference potential 34, unlike the vibration circuit 30A according to the first example embodiment, but is instead connected to a connection point C2 between the third switch 60 and the fourth switch 61 of the second leg 41B. Therefore, the piezoelectric element 15 is connected between the connection point C1 between the first switch 35 and the second switch 36 and the connection point C2 between the third switch 60 and the fourth switch 61. Note that the vibration circuit 30D according to the second example embodiment does not need to include the capacitor 39 included in the vibration circuit 30A according to the first example embodiment.

The third switch 60 is a MOSFET, for example, as with the first switch 35, but is not limited thereto. The third switch 60 has one end (source) and the other end (drain). One end of the third switch 60 is connected to the DC power supply 33. One end of the third switch 60 is also connected to one end of the first switch 35. The other end of the third switch 60 is connected to one end of the fourth switch 61. The other end of the third switch 60 is also connected to the end of the piezoelectric element 15 opposite to the end connected to the first leg 41A. The control circuit 32 is connected to a control end of the third switch 60 and can switch the third switch 60 on and off. The control circuit 32 can control the third switch 60 to electrically conduct/open a circuit between the DC power supply 33 connected to the third switch 60 and the piezoelectric element 15 by switching the third switch 60 on and off.

The fourth switch 61 is a MOSFET, for example, as with the first switch 35, but is not limited thereto. The fourth switch 61 has one end (source) and the other end (drain). One end of the fourth switch 61 is connected to the other end of the third switch 60. Specifically, one end of the fourth switch 61 is connected to the piezoelectric element 15, as with the other end of the third switch. The other end of the fourth switch 61 is connected to the reference potential 34 through the current-voltage conversion element 45 of the current-voltage conversion circuit 42A. The control circuit 32 is connected to a control end of the fourth switch 61 and can switch the fourth switch 61 on and off. The control circuit 32 can control the fourth switch 61 to electrically conduct/open a circuit between the piezoelectric element 15 connected to the fourth switch 61 and the reference potential 34 by switching the fourth switch 61 on and off.

### 2-2. Operation Example

An operation example of the excitation circuit 31D according to the second example embodiment will be described with reference to FIG. 13. FIG. 13 shows the vibration circuit 30D including the excitation circuit 31D and the piezoelectric element 15 as described above.

The control circuit 32 of the excitation circuit 31D according to the second example embodiment controls not only the first switch 35 and the second switch 36 but also the third switch 60 and the fourth switch 61 to be complementarily switched. Specifically, the control circuit 32 controls the switches 35, 36, 60, and 61 to be switched on and off so that the third switch 60 and the second switch 36 are synchronized and that the fourth switch 61 and the first switch 35 are synchronized. The control circuit 32 controls the first switch 35 to the fourth switch 61 so as to obtain a state (referred to as a “third state” as appropriate) where the second switch 36 and the fourth switch 61 are off when the first switch 35 and the third switch 60 are on. The control circuit 32 also controls the first switch 35 to the fourth switch 61 so as to obtain a state (referred to as a “fourth state” as appropriate) where the second switch 36 and the fourth switch 61 are on when the first switch 35 and the third switch 60 are off. The control circuit 32 can invert the polarity of the voltage applied to the piezoelectric element 15 by switching the switches 35, 36, 60, and 61 between the third state and the fourth state.

With the control circuit 32 operating as described above, the current detection circuit 38A can detect the current flowing from the DC power supply 33 to the reference potential 34 through the first switch 35, the piezoelectric element 15, and the fourth switch 61 in the third state. The current detection circuit 38A can also detect the current flowing from the DC power supply 33 to the reference potential 34 through the third switch 60, the piezoelectric element 15, and the second switch 36 in the fourth state. In the vibration circuit 30A according to the first example embodiment, the current detection circuit 38A detects the current only in the second state. However, in the vibration circuit 30D according to the second example embodiment, the current detection circuit 38A detects the current in each of the third state and the fourth state. Specifically, unlike the current detection circuit 38A according to the first example embodiment that detects the current flowing through the current-voltage conversion element 45 in the second state, the current detection circuit 38A according to the second example embodiment detects the current flowing through the current-voltage conversion element 45 in the third state and the fourth state, respectively. Therefore, the value outputted from the AD conversion circuit 44 to the control circuit 32 through the low pass filter 43 is substantially based on the sum of the currents flowing through the second switch 36 and the fourth switch 61. The excitation circuit 31D can thus improve a signal to noise ratio of the signal inputted from the AD conversion circuit 44 to the control circuit 32.

### Third Example Embodiment

### 3-1. Configuration Example

A vibration device according to a third example embodiment of the present disclosure will be described. Note that differences from the first example embodiment will be mainly described in the third example embodiment. In the third example embodiment, the same or equivalent configurations as those in the first example embodiment will be described with the same reference numerals. In the third example embodiment, overlapping descriptions with the first example embodiment will be omitted.

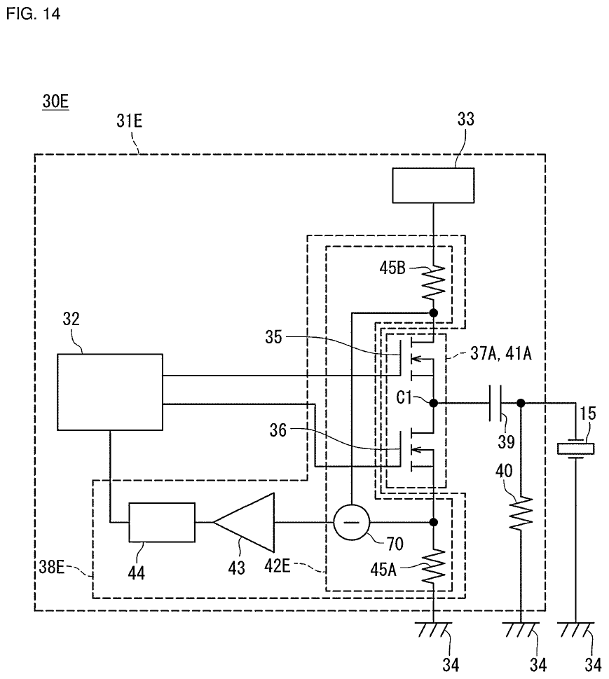

FIG. 14 is a schematic circuit diagram of a vibration circuit 30E including an excitation circuit 31E and a piezoelectric element 15 according to the third example embodiment of the present disclosure. The excitation circuit 31E according to the third example embodiment includes a current-voltage conversion circuit 42E instead of the current-voltage conversion circuit 42A. The current-voltage conversion circuit 42E of the excitation circuit 31E includes a current-voltage conversion element 45A between the second switch 36 and the reference potential 34, and a current-voltage conversion element 45B between the DC power supply 33 and the first switch 35. The current-voltage conversion element 45A corresponds to the current-voltage conversion element 45 in the first example embodiment. In this example embodiment, the current-voltage conversion elements 45A and 45B are resistors (shunt resistors) having a predetermined resistance value, as with the current-voltage conversion element 45, but are not limited thereto and may be a known element that can convert current to voltage, such as a Hall element.

The current-voltage conversion circuit 42E includes a difference circuit 70 between the connection point between the second switch 36 and the current-voltage conversion element 45A and the low pass filter 43. A connection point between the current-voltage conversion element 45B and the first switch 35 is connected to the difference circuit 70.

The difference circuit 70 is a differential amplifier circuit configured to have an amplification factor of 1, for example, but is not limited thereto, and any known circuit may be used. The current-voltage conversion element 45A converts the current flowing through the current-voltage conversion element 45A through the second switch 36 into a voltage corresponding to the magnitude of the current flowing through the current-voltage conversion element 45A. The current-voltage conversion element 45B also converts the current flowing through the current-voltage conversion element 45B through the first switch 35 into a voltage corresponding to the magnitude of the current flowing through the current-voltage conversion element 45B. The difference circuit 70 outputs a voltage indicating a difference between the voltage inputted from the current-voltage conversion element 45A and a voltage inputted from the current-voltage conversion element 45B to the low pass filter 43 as a detection voltage.

The current-voltage conversion element 45A is disposed on the low potential side (low side) with respect to the piezoelectric element 15. The current-voltage conversion element 45B is disposed on the high potential side (high side) with respect to the piezoelectric element 15. Considering FIG. 14 and the direction of the current, the voltages converted by the current-voltage conversion elements 45A and 45B have opposite polarities.

Therefore, once the difference circuit 70 acquires the difference between these voltages, the current flowing through the current-voltage conversion element 45B in the first state can be detected.

In the vibration circuit 30E according to the third example embodiment, the current detection circuit 38E detects the currents in the first state and the second state, respectively. Specifically, unlike the current detection circuit 38A that detects the current flowing through the current-voltage conversion element 45 in the second state, the current detection circuit 38E according to the third example embodiment detects the currents flowing through the current-voltage conversion elements 45A and 45B in the first state and the second state, respectively. Therefore, once the difference circuit 70 acquires the difference in voltage value based on the currents flowing through the current-voltage conversion elements 45A and 45B, the value outputted from the AD conversion circuit 44 to the control circuit 32 is substantially based on the sum of the currents flowing through the first switch 35 and the second switch 36. The excitation circuit 31E acquires the difference between the voltage values as described above, and thus can cancel common mode noise flowing through the elements 45A and 45B and can also improve a signal to noise ratio of the signal inputted from the AD conversion circuit 44 to the control circuit 32.

The current detection circuit 38E of the excitation circuit 31E according to this example embodiment uses the difference circuit 70 to acquire the difference between the voltages converted by the current-voltage conversion element 45A and the current-voltage conversion element 45B, but the present disclosure is not limited thereto. For example, when using Hall element for the current-voltage conversion elements 45A and 45B, the current detection circuit 38E may include an arithmetic circuit that adds voltages obtained by the Hall elements, instead of the difference circuit 70.

The excitation circuit, vibration device, and vehicle described in the present disclosure are realized by, for example, cooperation of hardware resources, such as a processor and a memory, and software resources (computer programs).

Example embodiments of the present disclosure provide excitation circuits, vibration devices, and vehicles that each detect the magnitude of a current flowing through a piezoelectric element while reducing the possibility of electrochemical migration occurring in the piezoelectric element. Example embodiments of the present disclosure are suitably applicable in these industrial fields.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An excitation circuit comprising:
an output circuit including a series circuit of a first switch and a second switch connected to a DC power supply, and including a connection point, between the first switch and the second switch, to which a piezoelectric element is connected;
a current detection circuit to detect at least one of a current flowing through the first switch and a current flowing through the second switch, and output a detection signal indicating a value based on the detected current; and
a control circuit to execute switching processing in which the first switch and the second switch are complementarily switched on and off at a switching frequency corresponding to a predetermined frequency, in order to apply a voltage of the predetermined frequency from the output circuit to the piezoelectric element, and that has a search mode to determine a resonant frequency of a vibrator including an object vibrated by the piezoelectric element and the piezoelectric element, based on a value indicated by the detection signal outputted from the current detection circuit.

2. The excitation circuit according to claim 1, wherein the current detection circuit includes:
a current-voltage conversion circuit to detect at least one of a current flowing through the first switch and a current flowing through the second switch, and output a detection voltage based on the detected current; and
a low pass filter to smooth the detection voltage from the current-voltage conversion circuit and output the smoothed detection voltage.

3. The excitation circuit according to claim 2, wherein the current detection circuit further includes an analog/digital conversion circuit to receive the smoothed detection voltage from the low pass filter and output a digital signal indicating the smoothed detection voltage from the low pass filter to the control circuit as the detection signal.

4. The excitation circuit according to claim 2, wherein the current-voltage conversion circuit includes:
a first current-voltage conversion element to convert the current flowing through the first switch into a voltage and output the voltage;
a second current-voltage conversion element to convert the current flowing through the second switch into a voltage and output the voltage; and
an arithmetic circuit to output to the low pass filter a voltage, as the detection voltage, indicating a difference or a sum of the current flowing through the first switch and the current flowing through the second switch, based on the voltage outputted by the first current-voltage conversion element and the voltage outputted by the second current-voltage conversion element.

5. The excitation circuit according to claim 1, further comprising:
a polarity inversion circuit to invert a polarity of the voltage applied to the piezoelectric element between when the first switch is on and the second switch is off and when the first switch is off and the second switch is on.

6. The excitation circuit according to claim 5, wherein the polarity inversion circuit includes a capacitor connected between the connection point between the first switch and the second switch and the piezoelectric element.

7. The excitation circuit according to claim 5, wherein the DC power supply is operative to output a positive voltage; and
the polarity inversion circuit includes a negative power supply circuit that is connected to the series circuit of the output circuit on an opposite side to the DC power supply to output a negative voltage.

8. The excitation circuit according to claim 1, wherein
the current detection circuit further includes a phase difference detection circuit to detect a phase difference between the current flowing through the second switch and the voltage applied to the piezoelectric element; and
the control circuit is operable to adjust the switching frequency based on the detected phase difference.

9. The excitation circuit according to claim 1, wherein
the search mode is operative to change the switching frequency in a first frequency range and acquire a change in the value of the detection signal in response to a change in the switching frequency in the first frequency range to determine the resonant frequency of the vibrator based on a frequency at which the value of the detection signal reaches a maximum within the first frequency range; and
the control circuit further includes a drive mode to repeat an operation of changing the switching frequency in a second frequency range that includes the resonant frequency of the vibrator and that is narrower than the first frequency range, acquire a change in the value of the detection signal in response to a change in the switching frequency within the second frequency range, and update the resonant frequency of the vibrator based on a frequency at which the value of the detection signal reaches a maximum within the second frequency range.

10. The excitation circuit according to claim 9, wherein the control circuit is operative to change a gain of the current detection circuit based on a frequency included in the first frequency range.

11. The excitation circuit according to claim 9, wherein the first frequency range includes a frequency that is 1/(2n+1) times or (2n+1) times the resonant frequency of the vibrator;
the second frequency range includes a resonant frequency of the vibrator, which is a frequency at which the value of the detection signal reaches a maximum within the second frequency range; and
n is a positive integer.

12. The excitation circuit according to claim 9, wherein the first frequency range includes the resonant frequency of the vibrator;
the second frequency range includes a frequency that is 1/(2n+1) times or (2n+1) times the resonant frequency of the vibrator, which is a frequency at which the value of the detection signal reaches a maximum within the second frequency range; and
n is a positive integer.

13. The excitation circuit according to claim 1, wherein
the piezoelectric element includes a first end and a second end;
the first end of the piezoelectric element is connected to the connection point between the first switch and the second switch; and
the second end of the piezoelectric element is connected to a reference potential having a lower potential than an output end of the DC power supply.

14. The excitation circuit according to claim 1, wherein
the output circuit further includes a series circuit of a third switch and a fourth switch connected to the DC power supply in parallel with the series circuit of the first switch and the second switch;
the piezoelectric element is connected between a connection point between the third switch and the fourth switch and the connection point between the first switch and the second switch;
an end of the first switch opposite to the second switch and an end of the third switch opposite to the fourth switch are connected to each other;
an end of the second switch opposite to the first switch and an end of the fourth switch opposite to the third switch are connected to each other; and
the switching processing complementarily switches on and off a pair of the first switch and the fourth switch and a pair of the second switch and the third switch at the switching frequency.

15. A vibration device comprising:
the excitation circuit according to claim 1;
the piezoelectric element; and
a light transmissive protective cover vibrated by the piezoelectric element.

16. The vibration device according to claim 15, wherein the current detection circuit includes:
a current-voltage conversion circuit to detect at least one of a current flowing through the first switch and a current flowing through the second switch, and output a detection voltage based on the detected current; and
a low pass filter to smooth the detection voltage from the current-voltage conversion circuit and output the smoothed detection voltage.

17. The vibration device according to claim 16, wherein the current detection circuit further includes an analog/digital conversion circuit to receive the smoothed detection voltage from the low pass filter and output a digital signal indicating the smoothed detection voltage from the low pass filter to the control circuit as the detection signal.

18. The vibration device according to claim 16, wherein the current-voltage conversion circuit includes:
a first current-voltage conversion element to convert the current flowing through the first switch into a voltage and output the voltage;
a second current-voltage conversion element to convert the current flowing through the second switch into a voltage and output the voltage; and
an arithmetic circuit to output to the low pass filter a voltage, as the detection voltage, indicating a difference or a sum of the current flowing through the first switch and the current flowing through the second switch, based on the voltage outputted by the first current-voltage conversion element and the voltage outputted by the second current-voltage conversion element.

19. The vibration device according to claim 15, further comprising:
a polarity inversion circuit to invert a polarity of the voltage applied to the piezoelectric element between when the first switch is on and the second switch is off and when the first switch is off and the second switch is on.

20. A vehicle comprising:
the vibration device according to claim 15; and
an imaging device to detect light transmitted through the protective cover.
